(19) United States
(12) Patent Application Publication
(10) Pub. No.: US 2009/0205705 A1
(43) Pub. Date: Aug. 20, 2009

(54) Method for Fabricating a Semiconductor Component With a Specifically Doped Surface Region Using Out-Diffusion, and Corresponding Semiconductor Component

(75) Inventors: Rolf Brendel, Hameln (DE); Barbara Terheiden, Hameln (DE); Andreas Wolf, Muhltal (DE)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Institut Fur Solarenergieforschung (ISFH), Emmerthal (DE)

(21) Appl. No.: 12/225,505

(22) PCT Filed: Mar. 20, 2007
(86) PCT No.: PCT/EP2007/002468

§ 371 Date: Mar. 17, 2009

(30) Foreign Application Priority Data
Mar. 21, 2006 (DE) 10 2006 013 313.7

(51) Int. Cl. H01L 31/04; H01L 21/20; H01L 29/36

(52) U.S. Cl. 136/252; 438/508; 257/655; 257/E21.09; 257/E29.109

(57) ABSTRACT

The invention proposes a method for producing a semiconductor component, such as a thin-layer solar cell. The method involves providing a doped semiconductor carrier substrate (1), producing a separating layer (2), for example a porous layer, on one surface of the semiconductor carrier substrate, depositing a doped semiconductor layer (3) over the separating layer and detaching the deposited semiconductor layer from the semiconductor carrier substrate. In line with the invention, process parameters such as the process temperature and time are chosen during the manufacturing process such that dopants can diffuse from the separation layer into the deposited semiconductor layer in order to form a specifically doped surface area (4). Specific use of solid-state diffusion makes it possible to simplify the manufacturing process over conventional fabrication methods in this manner.

### FIELD OF THE INVENTION

The present invention relates to a process for the production of a semiconductor component with a specifically doped surface area and the corresponding semiconductor component. In particular, the present invention relates to the production of a semiconductor component such as a thin layer solar cell using a layer transfer process.

### BACKGROUND TO THE INVENTION

The application of dopants to semiconductor materials is an essential part of the production process for semiconductor components. To produce a specifically doped area in a semiconductor component such as an emitter for a solar cell, it is usually necessary to have another process separate from the semiconductor component production sequence. For example, a phosphor-doped layer serving as an emitter can be produced in a boron-doped semiconductor substrate by POC1₃ diffusion.

In order to reduce the need for expensive semiconductor materials, semiconductor components are often manufactured using thin film technologies. This involves the deposition of thin semiconductor layers on a carrier substrate, e.g. by chemical vapour deposition (CVD). This gives the possibility of modifying the type and concentration of the doping during the processing and thus the production of one of several different dopant layers on semiconductor components. To achieve this, it is necessary for each individual layer to undergo a processing step with specific parameters e.g. for the composition of the vapour in the CVD deposition. In addition, intermediate steps are necessary, e.g. rinsing of the CVD reactor and modification of the vapour flow and/or changing the reactor.

### SUMMARY OF THE INVENTION

A need may arise for a simplified manufacturing process for a semiconductor component requiring the fewest possible processing steps and/or to avoid a modification of process parameters during the deposition of a thin semiconductor layer which is used for the semiconductor component.

This need can be fulfilled through the subject of the independent claims. Advantageous embodiments of the present invention are described in the dependent claims.

According to a first aspect of this invention, a method is proposed for the production of a semiconductor component with a specifically doped surface area where the process has the following steps: providing a doped semiconductor carrier substrate; creating of a separation layer on a surface of the semiconductor carrier substrate; depositing a doped semiconductor layer on the separation layer, and detaching the deposited semiconductor layer from the semiconductor carrier substrate. Such a process sequence may be identified as a layer transfer process. The process parameters used during the manufacturing process are so selected that dopants may be diffused from the separation layer into the deposited semiconductor layer in order to form the specifically doped surface area.

The characteristics, details and potential benefits of a manufacturing process in accordance with the invention will be presented.

By semiconductor component may be understood an electronic component based on a semiconductor substrate, the surface of which is doped in specific areas. The semiconductor substrate may be in the form of a thin semiconductor layer, for example, with a thickness of less than 50 μm, preferably less than 10 μm and strongly preferred from 1 to 5 μm. For instance, the semiconductor component to be produced may be a thin-film solar cell.

To produce the semiconductor component, first a doped semiconductor carrier substrate is provided. The semiconductor carrier substrate should preferably be a flat substrate and preferably made of silicon, particularly from mono-crystalline silicon. For instance, a strongly doped mono-crystalline silicon wafer can be used as the semiconductor substrate.

A separation layer can be created on a surface of the semiconductor carrier substrate which separation layer may form a predetermined breaking point for the subsequent detaching of the semiconductor layer from the semiconductor carrier substrate. The separation layer can be produced, for example, as a porous layer or produced as a system of layers made up of several overlapping porous layers, for example, through anodic etching. In this way, small cavities are etched in the surface of the semiconductor carrier substrate to form a spongy, porous and relatively unstable layer which can subsequently serve as the predetermined breaking point between the semiconductor carrier substrate and a semiconductor layer to be deposited. A possible etching process for the creation of a porous layer in a silicon wafer is described in DE 197 30 975 A1.

Alternatively, the separation layer may also be created, for example, by ion implantation which targets a layer at a certain distance below the surface of the semiconductor substrate to weaken it so that later it may serve as the predetermined breaking point.

A doped semiconductor layer will then be deposited on the separation layer. The semiconductor layer can thus be directly adjacent to the separation layer. Alternatively, an intermediate layer made, for example, of a dielectric, may also be located between the separation layer and the semiconductor layer. The semiconductor layer may also be deposited, for example, by using chemical vapour deposition (CVD), liquid phase epitaxy (LPE) or ion assisted deposition (lAD). The semiconductor material to be deposited may also be admixed during the deposition of the dopant so that on deposition, a doped semiconductor layer with a predetermined dopant concentration may be obtained.

Process parameters such as a process temperature during the deposition of the doped semiconductor layer or during a subsequent optional heat treatment step following the deposition of the doped semiconductor layer and associated processing periods corresponding thereto are selected such that, in accordance with the invention, dopants originating in the semiconductor carrier substrate at the separation layer are diffused in the deposited semiconductor layer. This may be performed directly during the deposition of the doped semiconductor layer or in a subsequent optional heat treatment step. Suitable process parameters such as the process temperature or temperature sequence and the process duration required to obtain a specifically doped surface area with a desired dopant concentration and a desired dopant profile may be determined, for example, by an appropriate series of tests as an expert would foresee them, or through computer simulations of the diffusion process.

If, for example, a thin-film silicon solar cell is to be created by using the production process in accordance with the invention, the process parameters can be adjusted to ensure that an emitter layer is formed in the specifically doped surface area with a layer resistance of less than 500 ohms/square, preferably less than 350 ohms/square and even more preferably, less than 200 ohms/square. With such a relatively strongly doped emitter in comparison to the rest of the semiconductor layer, a series resistance within the emitter and the related power losses for the solar cell can be minimised.

The process in accordance with the invention is based on the idea of using solid-state diffusion from the semiconductor carrier substrate to the semiconductor layer to be deposited thereon for the surface doping of a semiconductor component produced by means of a thin film method and which is then detached from the semiconductor carrier substrate used in the manufacture.

This leads, inter alia, to a simplification of the manufacturing process as areas do not have to be in-diffused in the semiconductor layer subsequently as is conventionally the case, or alternatively, dopant concentrations do not have to be varied during the deposition of the semiconductor layer. Instead, the semiconductor layer may be continuously deposited with a steady dopant concentration and due to the process parameters selected during preparation, dopants diffuse from the separation layer into the deposited, or to be deposited, semiconductor layer, and thus form specifically doped surface areas whose doping may be the same type or opposing to the type of conduction of the remaining semiconductor layer and whose dopant concentration may be different from that of the remaining semiconductor layer. In this way, p/n, p/p⁺ or n/n⁺ structures are created in the semiconductor layer.

It is also advantageous that the specifically doped areas of the semiconductor components produced through solid-state diffusion have a relatively low surface doping concentration which corresponds to the maximum of that of the semiconductor substrate. Such weakly doped surfaces are especially preferred, e.g. for solar cells because they can be passivated better.

Another advantage is that the semiconductor substrate can be used again several times.

According to one embodiment, the production process also has a subsequent heat treatment related to the deposition of the doped semiconductor layer. By heat treatment may be understood the maintaining of the semiconductor carrier substrate along with the ensuing deposited semiconductor layer at a certain temperature of, for example, more than 800° C., preferably more than 900° C. and even more preferably at more than 1000° C. for a certain period of time. The higher the selected temperature, the faster is the solid-state diffusion. The process period may, depending on the process temperature, be in the range of from a few minutes to several hours. For example, a processing time of 60 minutes at a process temperature of 1100° C. may result in an in-diffusion of doped surface areas sufficient to produce the dopant concentration for the emitter of a solar cell.

According to a further embodiment, the deposition of the semiconductor layer is performed at a temperature of more than 800° C., preferably more than 900° C. and even more preferably at more than 1000° C. By selecting the temperature as high as possible during deposition in the semiconductor layer, this may already lead to a significant solid-state diffusion, during the deposition, of dopants from the semiconductor substrate carrier into the semiconductor layer to receive the dopants. In this way, the need for additional heat treatment to achieve solid-state diffusion for satisfactorily doped surface areas may be avoided or the duration of such a heat treatment may be shortened.

According to another embodiment, a semiconductor carrier substrate is used for the manufacturing process with a dopant concentration of at least 1×10¹⁸ cm⁻³, preferably at least 1×10¹⁹ cm⁻³ and even more preferably 1×10²⁰ cm⁻³ in an area near the surface. The higher the doping concentration on the surface of the semiconductor carrier substrate or in an area near the surface, e.g. a few tens or hundreds of nanometres below the surface, the stronger is the solid-state diffusion from the semiconductor carrier substrate into the semiconductor layer. Depending on how the high doping concentration is created in an area near the surface of the semiconductor substrate, one can achieve even higher dopant concentrations of more than 5×10²⁰ cm⁻³, preferably more than 1×10²¹ cm⁻³, which can be beneficial for the solid-state diffusion effect. The strongly doped areas near the surface may be produced, for example, by a conventional POC1₃ diffusion in the semiconductor carrier substrate before the semiconductor layer is deposited on the semiconductor carrier substrate or the separation layer situated thereon.

According to another embodiment, a semiconductor carrier substrate is used for the manufacturing process with an essentially homogeneous basic doping. “Essentially homogeneous” may be taken to mean here that the doping of the semiconductor substrate carrier varies by less than 50%, preferably less than 20% and even more preferably by less than 5%. In other words, unlike the embodiment described above, the semiconductor carrier substrate does not only have a strongly doped area near the surface. Instead, the semiconductor substrate carrier is subject to strong doping throughout its entire thickness, leading to a conductivity of less than 50 mOhm-cm, preferably less than 10 mOhm-cm and even more preferably less than 3 mOhm-cm. As strong as possible a basic doping of the basic semiconductor carrier substrate can, in turn, be beneficial for the solid-state diffusion. It may therefore be preferable to use a semiconductor carrier substrate with the maximum technically achievable basic doping. For example, a silicon carrier substrate with boron doping may be used where the boron concentration is selected at maximum solubility. Alternatively, other substrates may be doped with other dopants such as phosphorus or gallium with a doping concentration at maximum solubility.

If, according to another embodiment, the doping at a surface of the semiconductor carrier substrate and the doping of deposited or to be deposited semiconductor layers are selected of an opposing type of conduction, then a pn junction may be generated between the emitter formed by in-diffusion and a basis formed by the remainder of the semiconductor layer through in-diffusion of dopants from the carrier substrate into the semiconductor layer.

According to another embodiment, the manufacturing process can be particularly beneficially affected if a layer transfer process called the PSI method is used. This procedure is described in detail, for example, in DE 197 30 975 A1. In this method, a porous layer system is created through anodic etching on a surface of a semiconductor carrier substrate.

As the etching process parameters used may be varied during the etching process it may be achieved that, the porous layer system may have a lower layer with a high porosity of, for example, 40% or more, and thereover, which means towards the outside of the semiconductor carrier substrate, may have an upper layer with a lower porosity of, for example, 35% or less. The high porosity lower layer can serve subsequently as the predetermined breaking point when detaching the semiconductor layer deposited on the upper layer.

In order to condense the upper layer more, after anodic etching, the semiconductor carrier substrate is traditionally subjected to a so-called baking or annealing step at an increased temperature of, for example, 1100° C. and for a duration of e.g. 30 minutes. However, as such an annealing step causes out-diffusion of the dopant from the porous layer into the surrounding atmosphere, this reduces the doping concentration within the porous layer. However, as described above, a lower dopant concentration can lead to disadvantages for the solid-state diffusion. It can, therefore, be advantageous for the manufacturing process in accordance with the invention to keep the annealing step to a minimum, for example, less than 10 minutes, preferably less than 5 minutes, or even omit it entirely.

According to another embodiment, the manufacturing process also includes the formation of electrically conductive contacts on surfaces of the semiconductor layer. These contacts are applied before and/or following detaching of the semiconductor layer from the semiconductor carrier substrate, for example, by evaporation. For example, the contacts may be metallic. In this way, a thin-film solar cell will be formed. On an incident light side of the solar cell, finger-shaped contacts can be formed, for example, or by using a transparent conductor. As an option, additional dielectric layers may be formed on the surface of the semiconductor layer in order to reduce surface recombination.

According to other aspects of this invention, a semiconductor component or a solar cell is proposed as being able to be produced using the above-described manufacturing processes.

It will be noted that the embodiments, characteristics and advantages of the invention are mainly in relation to manufacturing processes based on the invention. However, on the basis of the above and also from the following description, an expert will recognise that, insofar as it is not indicated otherwise, that the embodiments and characteristics of the invention can also be transferred in an analogous manner to the semiconductor component or solar cell in accordance with the invention. In particular, the characteristics of the various embodiments may be combined in any preferred manner.

Other characteristics and advantages of the present invention will become obvious to an expert from the following description of an exemplary embodiment, but to which the invention is not limited, and with reference to the accompanying drawing.

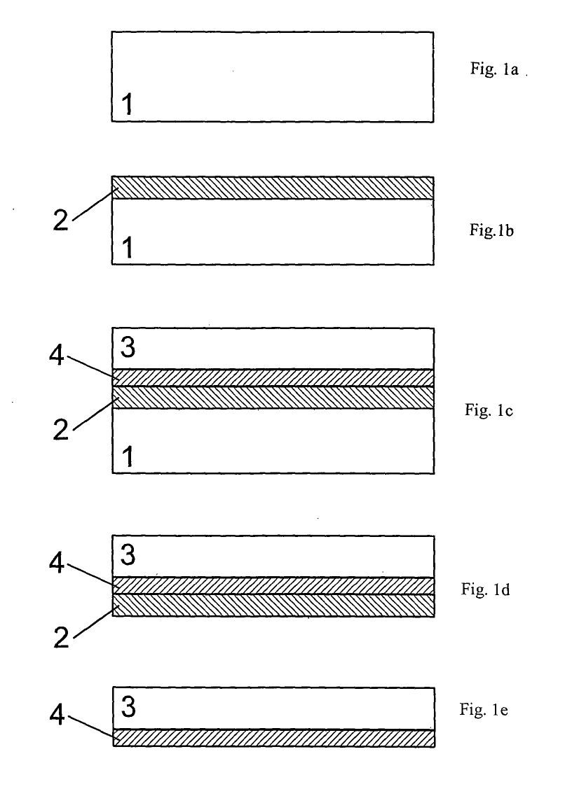

FIGS. 1a to 1e schematically illustrate a production sequence according to an embodiment of the present invention.

In the following, with reference to FIG. 1, a production sequence according to an embodiment of the present invention is described for the production of a specifically doped area using a semiconductor component produced through layer transfer technology (FIGS. 1a to 1e).

a) A carrier substrate (1) with suitable properties is selected. This may be, for example, a semiconductor disc or a glass or ceramic substrate. The carrier substrate can be structured and/or provided with semiconductor or dielectric layers or have local or n- or p-doped areas.

b) The carrier substrate is prepared for the layer transfer process (FIG. 1b), e.g. by creating a porous layer system on its surface (e.g. PSI process, patent DE000019730975A1). This step allows the subsequent detachment of the semiconductor component. Other treatments may be performed, such as the introduction of the desired dopant substance into the carrier substrate (1) and/or the area (2) of the carrier substrate prepared for the layer transfer.

c) The semiconductor layer (3) is grown (for example, through CVD). While growing, or as a result of a subsequent heat treatment, dopant substance wanders from the carrier substrate (1) and/or from the area of the carrier substrate prepared for the layer transfer (2) into the semiconductor layer (3) and creates a specifically doped area (4) in the semiconductor layer (FIG. 1c).

d) The grown semiconductor layer (3), including the specifically doped area (4) is detached from the carrier substrate. There may remain a part of the carrier substrate (2) on the detached semiconductor layer (FIG. 1d).

e) Any residual amounts of the carrier substrate (2) will be removed insofar as this is necessary for subsequent processes (FIG. 1e)

As a result, one obtains a semiconductor component which has a specifically doped area (4) on the side facing the carrier substrate. Another feature is that the dopant substance required for the production of the specifically doped area (4) is made available from the carrier substrate (1) or areas of the carrier substrate (2) and need not be provided during the layer growth as a result of the growth process (e.g. CVD through the vapour phase). This allows a quick and easy process for the layer growth because during the layer growth, the deposition parameters (in particular with respect to the type and concentration of the doping) need not be varied. In this way, the manufacture of semiconductor components with such a doped area is simplified.

Finally, the background and characteristics of the invention are again explained in other words:

It is possible to use the out-diffusion of dopant substance from the carrier substrate or other sources and the renewed application of this dopant substance into the growing layer. If the transport of dopant substance takes place during the vapour phase, this phenomenon is referred to as “auto doping”. If the dopant substance is diffused from neighbouring layers or from the carrier substrate into the growing layer, then this is referred to as “solid-state diffusion”. The out-diffusion of dopant substance through epitaxy processes is usually not desirable. However, there are applications which control and purposeful use this phenomenon to produce a specific dopant profile in the grown layer (See, for example, B. M. Abdurakhmanov and R. R. Bilyalov, Semicond. Sci. Technol. 11 (1996) pp. 921-926 and U.S. Pat. No. 4,925,809, U.S. Pat. No. 4,466,171, U.S. Pat. No. 4,379,726, U.S. Pat. No. 4,170,501, U.S. Pat. No. 4,132,573 and U.S. Pat. No. 4,032,372). This is also the case with the process of the present invention.

The present invention relates to the production of a semiconductor component, such as a solar cell, using a layer transfer technology. The production includes, among other things, the generation of a desired spatial dopant substance distribution to produce n-conducting and/or p-conducting areas in the semiconductor layer. The necessary dopant substance must be applied in the semiconductor layer either during the layer growth or during subsequent processes.

The present invention makes possible the creation of a specifically doped area of the n- or p-conducting type in a semiconductor layer. The production of the semiconductor layer is performed with a layer transfer technology (such as, for example, that known as the PSI process and as described in the German patent application DE 000019730975 A1). The semiconductor layer is deposited on a carrier substrate. The carrier substrate is prepared beforehand so that the grown semiconductor layer can be detached from the carrier substrate in a controlled manner.

A task of the invention can lie in the possibly simplified manufacture of a specifically doped area. The aim is to make possible the production of the specifically doped area without the need for any further subsequent processes for the growth of the semiconductor layer. Furthermore, the growth process itself can be so controlled that, in particular, the type and concentration of the doping of the grown semiconductor layer need not be varied during the layer growth. This should allow simpler processing.

In accordance with preferred embodiments, the present invention uses the above-mentioned phenomenon of out-diffusion of dopant substance in high-temperature processes (solid-state diffusion) in order to solve the set task. In this way, the carrier substrate or layers or areas on it serve as a source of dopant substance which is diffused from the source into the grown semiconductor layer. This diffusion process takes place during the deposition of the semiconductor layer and/or during a subsequent heat treatment. A specifically doped area results from this out-diffusion from the substrate on the side facing the semiconductor layer and for which neither a separate production process nor a modification of the dopant substance supplied is necessary during the growth process. The specifically doped area is also doped “automatically” during the layer growth and/or during subsequent heat treatment. This will greatly simplify its production.

In particular, by appropriate choice of the dopant substance made available from the source (such as boron or phosphorus), the conducting type of the specific doped area may be selected to be n or p type. The conducting type of the grown semiconductor layer may likewise be selected by the addition of dopant substance during the layer growth to be n or p type. This enables both pn junctions as well as junctions from a low to a high dopant concentration (p/p+ or n/n+) to be implemented.

The present invention shows, when compared with the above inventions (U.S. Pat. No. 4,925,809, U.S. Pat. No. 4,466,171, U.S. Pat. No. 4,379,726, U.S. Pat. No. 4,170,501, U.S. Pat. No. 4,132,573 and U.S. Pat. No. 4,032,372), the fact that the use of out-diffusion of dopant substance from the substrate makers into the growing semiconductor layer is combined on the one hand with a layer transfer technology, and on the other with the subsequent detachment of the grown semiconductor layer including the resultant specifically doped area. In this way, the side of the semiconductor layer becomes accessible which side carries the specifically doped area. This allows the treatment of the surface of this area, e.g. for surface passivation and provision of electrical contacts. Another advantage of this invention lies in the reusability of the carrier substrate not only as a growth substrate but also as a source of dopant substance.

On this point, the reusability of the dopant substance source sets the present invention apart from the above inventions.

Examples of embodiments of the invention may be described in accordance with the following proposals:

1) Production process to obtain a specifically doped area in a semiconductor component produced using a layer transfer process, wherein the carrier substrate and/or a part or area of the substrate or a layer applied on the carrier substrate is used as a source of dopant substance, whereby during the growth of the semiconductor layer and/or during subsequent heat treatment, a specifically doped area is created in the growing layer. The carrier substrate can be reused as a dopant substance source.
2) Process for the production of a semiconductor component based on a transfer layer in accordance with proposal 1 above, wherein there is a pn-junction or n/n+ or p/p+junction in the layer and the specifically doped area of the layer.
3) Process for the production of a semiconductor component based on a transfer layer in accordance with proposal 1 above, wherein the semiconductor component is a solar cell.
4) Process for the production of a semiconductor component based on a layer transfer in accordance with proposal 1 above, wherein the PSI process (patent DE000019730975A1) is used for the layer transfer.
5) Process for the production of a semiconductor component based on a layer transfer in accordance with proposal 1 above, wherein the semiconductor layer is grown through chemical vapour deposition (CVD), liquid phase epitaxy (LPE) or ion assisted deposition (lAD) or any other relevant process.
6) Semiconductor component characterised by the fact that in the manufacture, a process in accordance with proposals 1, 2, 3, 4 or 5 is used.

### REFERENCE SIGNS LIST

1 Carrier substrate
2 Area of the carrier substrate prepared for the layer transfer
3 Grown semiconductor layer
4 Specifically doped area of the grown semiconductor layer produced by out-diffusion

1. A process for production of a semiconductor component with a specifically doped surface area, featuring:
providing a doped semiconductor carrier substrate;
creating a separation layer on a surface of the semiconductor carrier substrate;
depositing a doped semiconductor layer above the separation layer; and
detaching the deposited semiconductor layer from the semiconductor carrier substrate,
wherein process parameters including at least one parameter from the group comprising process temperature, process temperature sequence and process duration are selected to ensure that dopants diffuse from the separation layer into the deposited semiconductor layer in order to form a doped surface area, wherein the doped surface area has relatively strong doping in comparison to the remaining semiconductor layer so that the surface area has a sheet resistance of less than 500 ohms/square.

2. The process in accordance with claim 1, where a porous layer is produced on the semiconductor carrier substrate as the separation layer.

3. The process in accordance with claim 1, further comprising a subsequent heat treatment following the deposition of the doped semiconductor layer.

4. The process in accordance with claim 3, where the semiconductor carrier substrate together with the deposited semiconductor layer is kept at a temperature of more than 800° C. during the heat treatment.

5. The process in accordance with claim 1, where the deposition of the semiconductor layer is performed at a temperature of more than 800° C.

6. The process in accordance with claim 1, where the semiconductor carrier substrate has a dopant concentration of at least 1×10¹⁸ cm⁻³ in an area near the surface.

7. The process in accordance with claim 1, where the semiconductor carrier substrate has an essentially homogeneous basic doping for a conductivity of less than 50 milliohm-centimetre.

8. The process in accordance with claim 1, where the doping on a surface of the semiconductor carrier substrate and the doping of the deposited semiconductor layer are of opposing conducting types.

9. The process in accordance with claim 1, where the doping on a surface of the semiconductor carrier substrate and the doping of the deposited semiconductor layer are of the same conducting type.

10. The process in accordance with claim 1, where a PSI process is used as a layer transfer procedure.

11. The process in accordance with claim 1, where the semiconductor layer is deposited through one of chemical vapour deposition, liquid phase epitaxy and ion assisted deposition.

12. The process in accordance with claim 1, further comprising a formation of electrically conductive contacts on surfaces of the semiconductor layer to form a solar cell.

13. A semiconductor component produced with a process in accordance with claim 1.

14. A solar cell produced with a process in accordance with claim 1.
